(19) United States
(12) Patent Application Publication
(10) Pub. No.: US 2009/0085156 A1
(43) Pub. Date: Apr. 2, 2009

(54) METAL SURFACE TREATMENTS FOR UNIFORMLY GROWING DIELECTRIC LAYERS

(76) Inventors: Gilbert Dewey, Hillsboro, OR (US); Matthew V. Metz, Hillsboro, OR (US); Jack Kavalieros, Portland, OR (US); Robert S. Chau, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/864,904

(22) Filed: Sep. 28, 2007

(51) Int. Cl. H01L 29/00; H01L 21/02

(52) U.S. Cl. 257/532; 438/393; 257/E29.001; 257/E21.011

(57) ABSTRACT

A fabrication process for a MIM capacitor comprises providing a substrate, depositing a first metal layer on a dielectric layer of the substrate, forming an interfacial layer on the first metal layer, wherein the interfacial layer has a hydroxyl terminated surface, depositing a capacitor dielectric layer on the interfacial layer using an ALD process, and depositing a second metal layer on the capacitor dielectric layer. The interfacial layer may be formed by depositing a thin layer of a metal oxide, by oxidizing a surface of the first metal layer with an oxygen plasma, or by evaporating a thin metal oxide onto the surface of the first metal layer.

### BACKGROUND

In the manufacture of integrated circuit devices, metal-insulator-metal (MIM) capacitors are fabricated by depositing a layer of dielectric material between two metal layers. As integrated circuit device dimensions continue to scale down, it is critical that the thickness of the dielectric layer used in the MIM capacitor be minimized as well.

The fabrication process for a conventional MIM capacitor includes forming a bottom metal layer, forming a dielectric layer on the bottom metal layer, and forming a top metal layer on the dielectric layer. Unfortunately, the surface of the bottom metal layer tends to be a hydrogen terminated surface. As such, when an atomic layer deposition (ALD) process is used to deposit the dielectric layer, the dielectric layer suffers from poor, non-uniform growth.

For instance, instead of depositing as a uniform monolayer, the dielectric layer begins nucleating at numerous discrete locations on the metal surface. Growth of the dielectric then spreads from those locations. This is referred to in the art as “island growth”. If a thin dielectric layer is formed, this island growth pattern causes the resulting thin dielectric layer to have a high level of oxide leakage. The thin dielectric layer will also be more prone to defects. To counter such issues, conventional MIM fabrication processes deposit thicker dielectric layers so that a desired low level of oxide leakage can be achieved and defects can be minimized. This presents a problem, however, since a thin dielectric layer is highly desired to form smaller capacitors capable of storing a greater amount of charge for a given leakage current.

Accordingly, improved deposition methods for dielectric layers on metal surfaces is needed.

### BRIEF DESCRIPTION OF THE DRAWINGS

FIG. 1 is a method 100 of forming a MIM capacitor device for use in a 1T1C memory cell.

FIGS. 2A to 2E illustrate structures that are formed when the method 100 of FIG. 1 is carried out.

### DETAILED DESCRIPTION

Described herein are systems and methods of uniformly depositing a dielectric layer on a metal surface. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide a fabrication process by which metal-insulator-metal (MIM) capacitors may be formed using thin dielectric layers that satisfy MIM capacitor leakage requirements. This is accomplished by using metal surface pre-treatments that enable uniform growth of the dielectric layer by suppressing island growth during an atomic layer deposition (ALD) process. The result is a higher quality dielectric layer with less defects and lower oxide leakage, thereby allowing a thinner dielectric layer to be used in the MIM capacitor. The resulting MIM capacitor can then store more charge for a given leakage current and the capacitor area can be reduced. For memory applications, such as 1T1C (1 transistor 1 capacitor) memory cells, this enables memory density to improve, which is a key component for enabling the scaling of memory applications that use a capacitor storage node.

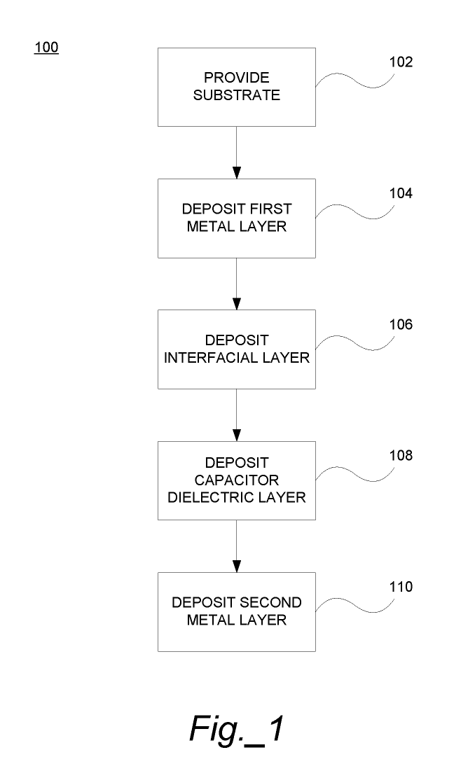

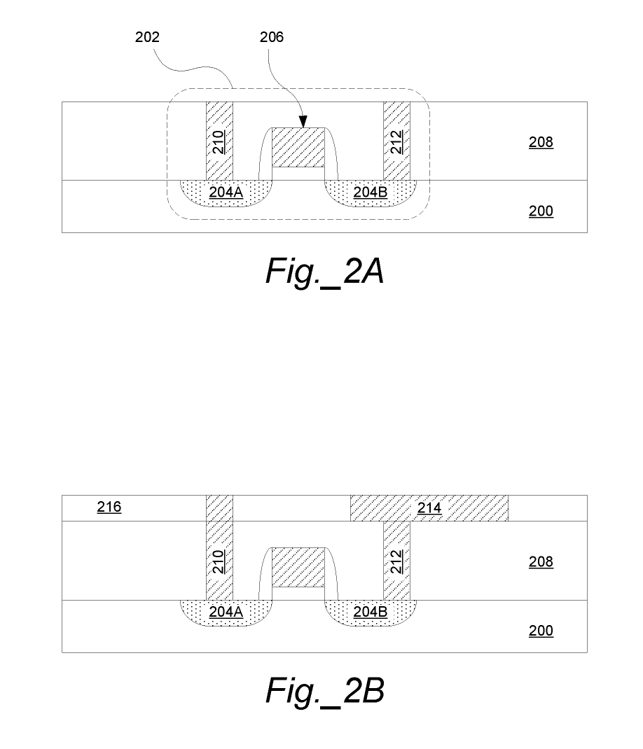

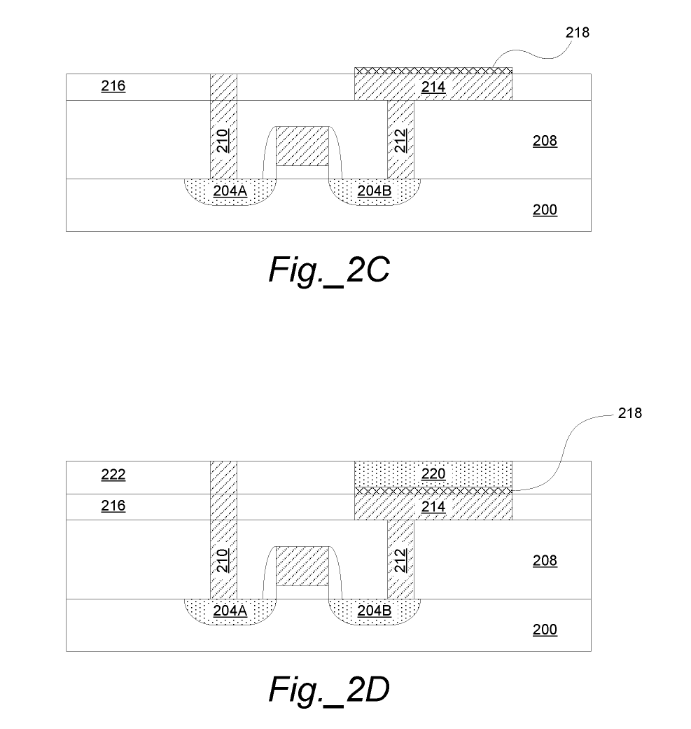

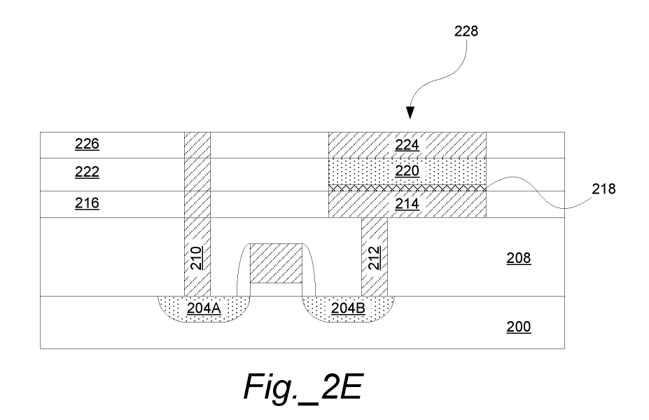

FIG. 1 is a method 100 of forming a MIM capacitor device for use in a 1T1C memory cell, in accordance with an implementation of the invention. FIGS. 2A to 2E illustrate structures that are formed when the method 100 of FIG. 1 is carried out.

The method 100 of FIG. 1 begins by providing a substrate upon which a MIM capacitor device is to be fabricated (process 102 of method 100). The substrate is typically a semiconductor substrate formed using a single-crystal silicon or a silicon-on-insulator (SOI) substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention.

The semiconductor substrate generally includes one or more layers of material on its surface, such as semiconductive layers, dielectric layers, and conductive layers that have been photolithographically patterned and etched to form semiconductor device features over, on, or within the substrate. The semiconductive layers may include one or more of epitaxial silicon, polysilicon, amorphous silicon, doped polysilicon, or the like.

The dielectric layers may be formed using materials known for the applicability in dielectric layers for integrated circuit structures, such as one or more of silicon dioxide (SiO₂), fluorinated SiO₂, carbon doped oxide (CDO), silicon nitride (SiN), tetraethylorthosilicate (TEOS), borophosphosilicate glass (BPSG), fluorosilicate glass (FSG), spin on glass (SOG), low-k materials, high-k materials, organic polymers such as perfluorocyclobutane or polytetrafluoroethylene, inorganic polymers, and organosilicates such as silsesquioxane, siloxane, or organosilicate glass. The dielectric layer may include pores or other voids to further reduce its dielectric constant. The dielectric layer may include one or more trenches and/or vias within which metal interconnects and metal vias will be formed. The trenches and/or vias may be patterned using conventional wet or dry etch techniques that are known in the art.

The conductive layers include metal interconnects and metal vias. These structures are generally formed of one or more of refractory silicides, refractory metals, aluminum, copper, tungsten, alloys of these materials, conductive nitrides, conductive oxides, or the like. Each conductive layer also includes interlayer dielectric (ILD) material surrounding and insulating the metal interconnects and the vias.

Integrated circuit devices such as transistors, inductors, and diodes may be formed on the surface of the substrate or within its layers. For instance, if a MIM capacitor device is being fabricated for a 1T1C memory cell, the substrate will generally have transistors already formed upon its surface.

FIG. 2A illustrates a substrate 200 upon which a MIM capacitor device may be constructed in accordance with an implementation of the invention. As noted above, the substrate 200 is formed using a material such as single-crystal silicon or a SOI substructure. The substrate 200 may include a transistor 202 formed upon its surface. Those of skill in the art will recognize transistor 202 as being a planar transistor having a diffusion region 204A, a diffusion region 204B, and a gate stack 206. An insulating layer 208 may be formed on the substrate 200 and around the transistor 202. As shown, a metal via 210 is formed on the diffusion region 204A that can be used to couple the transistor 202 to a bit line. Also shown is a metal via 212 formed on the diffusion region 204B that can be used to couple the transistor 202 to a MIM capacitor device to be formed in accordance with at least one implementation of the invention.

Returning to FIG. 1, a deposition process is carried out to form a first metal layer on the substrate (104). More specifically, in an implementation of the invention where a 1T1C memory cell is being formed, the first metal layer may be formed on a dielectric layer of the substrate at a location that enables the first metal layer to be electrically coupled to a transistor formed on the substrate. For instance, the first metal layer may be formed on a via that is electrically coupled to the transistor. The first metal layer may be formed using any of a variety of techniques known in the art for forming a metal layer on a substrate. In some implementations, a deposition process such as ALD, chemical vapor deposition (CVD), physical vapor deposition (PVD), sputtering, electroless plating, or electroplating may be used. Metals that may be used in the first metal layer include, but are not limited to, copper, aluminum, magnesium, tin, zirconium, indium, tungsten, and silver, as well as alloys of two or more of these metals.

In some implementations, a damascene process may be used to form the first metal layer. In such a process, a dielectric layer (e.g., an ILD layer) or a photoresist layer may be deposited and patterned to form a recess that defines the first metal layer. The patterning process may be carried out using conventional lithography processes, as will be recognized by those of skill in the art. A metal layer may then be deposited within the recess using any of the above mentioned deposition processes. A chemical mechanical polishing (CMP) process may follow to planarize the deposited metal layer and remove excess metal from outside the boundaries of the recess, yielding a first metal layer confined within the recess. If a dielectric layer is used to form the recess, it will generally remain intact after the CMP process. If a photoresist layer is used to form the recess, it will generally be removed and replaced with a dielectric layer.

In other implementations, a blanket metal layer may be deposited over the substrate using any of the above listed deposition processes. An etching processes may follow to pattern the metal layer and form the first metal layer to be used in the MIM capacitor device of the invention. An ILD layer may then be deposited and planarized to surround the first metal layer.

In yet another implementation, a metal seed layer or a metal-immobilization process (MIP) may form an activated surface upon which the first metal layer may be formed using an electroless plating or electroplating process. Such techniques are well known in the art and will not be discussed here. Again, a dielectric layer may then be deposited and planarized to surround the first metal layer.

FIG. 2B illustrates a first metal layer 214 that has been formed within an ILD layer 216 over the substrate 200. The first metal layer 214 is formed at a location over the via 212, thereby electrically coupling the first metal layer 214 to the transistor 202. The first metal layer 214 has a thickness between around 1 nm and 100 nm, and is generally between 1 nm and 10 nm. As mentioned above, metals that may be used in the first metal layer include, but are not limited to, copper, aluminum, magnesium, tin, zirconium, indium, tungsten, and silver, as well as alloys of two or more of these metals.

As noted above, the exposed surface of the first metal layer will tend to be a hydrogen terminated surface. Unfortunately, dielectric layers deposited using an ALD process tend to nucleate and grow poorly on such surfaces. As explained above, dielectric layers formed on hydrogen terminated surfaces using an ALD process tend to suffer from an island growth pattern, resulting in high defects and high current leakage.

Therefore, in accordance with implementations of the invention, a pre-treatment process is carried out to fabricate a relatively thin interfacial layer over the surface of the first metal layer (106). The interfacial layer replaces the hydrogen terminated surface of the first metal layer with a hydroxyl (OH) terminated surface. The hydroxyl terminated surface is more reactive than the hydrogen terminated surface with respect to the precursors used to deposit the first metal layer and the precursors used to deposit the subsequent capacitor dielectric layer. This enables a high quality, uniform dielectric layer to be grown over the first metal layer since dielectric material can be deposited in a monolayer manner on a hydroxyl terminated surface using an ALD process. The thickness of the interfacial layer may range up to around 6 Angstroms (Å).

In one implementation of the invention, an interfacial layer may be formed by growing or depositing a thin layer of a metal oxide. In some implementations, a monolayer of the metal oxide may be used. In other implementations, the thickness of the metal oxide layer may range up to around 6 Å. Metal oxides that may be used here include, but are not limited to, titanium oxide (TiO), tantalum oxide (TaO), and titanium oxynitride (TiON). Conventional deposition processes may be used to deposit the metal oxide layer. The metal oxide layer provides a hydroxyl terminated surface.

In another implementation of the invention, an interfacial layer may be formed by oxidizing the surface of the first metal layer with an oxygen (O₂) plasma. The exposure to the oxygen plasma may be relatively minimal, resulting in a relatively thin interfacial layer. As will be recognized by those of skill in the art, the specific process parameters for the oxygen plasma application will be very dependent on the plasma chamber parameters, the material being oxidized, and the gas mixture used to oxidize the material. For instance, some materials may require an oxygen plasma application of less than five seconds at a power of less than 100 Watts. The application of the oxygen plasma converts the surface of the metal to a hydroxyl terminated surface.

In yet another implementation of the invention, an interfacial layer may be formed by evaporating a thin metal oxide onto the surface of the first metal layer. Metal oxides that may be used here include, but are not limited to, aluminum oxide (Al₂O₃), hafnium oxide (HfO₂), zirconium oxide (ZrO₂), and tantalum oxide (Ta₂O₅). The thickness of the metal oxide layer may range from around 1 Å to around 6 Å. Processes for evaporating metals are well known and will vary based on the chamber parameters.

FIG. 2C illustrates an interfacial layer 218 that has been formed over the first metal layer 214. As noted above, the interfacial layer 218 has a thickness that ranges up to around 6 Å and provides a hydroxyl terminated surface upon which a dielectric layer may be uniformly grown.

A capacitor dielectric layer may be deposited on the interfacial layer (108). In most implementations, a conventional ALD process will be used to deposit the capacitor dielectric material. Since the interfacial layer has a hydroxyl terminated surface, the ALD process will deposit the dielectric material monolayer by monolayer, thereby forming a high-quality dielectric layer with relatively fewer defects and lower oxide leakage. As a result, the thickness of the capacitor dielectric material may be reduced, thereby enabling the MIM capacitor device to be scaled down.

The specific dielectric that is chosen may be any dielectric material that is appropriate for use within a MIM capacitor device. For instance, dielectric materials that may be deposited on the interfacial layer include, but are not limited to, silicon dioxide, silicon nitride, and high-k dielectric materials such as hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

In alternate implementations, deposition methods such as CVD or PVD may be used. In various implementations of the invention, a blanket layer of the dielectric material may be deposited and patterned using conventional lithography techniques to form the capacitor dielectric layer. The capacitor dielectric layer will generally cover at least a portion of the interfacial layer. Another dielectric layer, such as an ILD layer, may be formed around the capacitor dielectric layer.

FIG. 2D illustrates a capacitor dielectric layer 220 that has been formed on the interfacial layer 218. An ILD layer 222 surrounds the capacitor dielectric layer 220. The capacitor dielectric layer 220 has a thickness between around 3 nm and around 20 nm.

After the high quality, uniform dielectric layer is formed for use as a capacitor dielectric layer, a deposition process is carried out to form a second metal layer on the capacitor dielectric layer (110). This generally completes formation of the MIM capacitor device. The second metal layer may be formed using any of a variety of techniques known in the art for forming a metal layer on a dielectric layer. In some implementations, a deposition process such as ALD, CVD, PVD, sputtering, electroless plating, or electroplating may be used. Metals that may be used in the second metal layer include, but are not limited to, copper, aluminum, magnesium, tin, zirconium, indium, tungsten, and silver, as well as alloys of two or more of these metals.

In some implementations, a damascene process may be used to form the second metal layer. Such a process was described above for the first metal layer. In other implementations, a blanket metal layer may be deposited over the dielectric layer using any of the above listed deposition processes. An etching processes may follow to pattern the metal layer and form the second metal layer. In yet another implementation, a MIP process may be used to provide an activated surface upon which the second metal layer may be formed using an electroless plating or electroplating process. Such techniques are well known in the art and will not be discussed here. An ILD layer may then be deposited and planarized to surround the second metal layer.

FIG. 2E illustrates a second metal layer 224 that has been formed within an ILD layer 226 over the capacitor dielectric layer 220, thereby forming a MIM capacitor device 228. The second metal layer 224 has a thickness between around 1 nm and 100 nm. As mentioned above, metals that may be used in the first metal layer include, but are not limited to, copper, aluminum, magnesium, tin, zirconium, indium, tungsten, and silver, as well as alloys of two or more of these metals.

Further processing may complete fabrication of the bit line coupled to the transistor for the 1T1C memory cell being formed. For instance, as shown in FIGS. 2B through 2E, metal vias were formed above the via 210 that can electrically couple the via 210 to a bit line. Further processing may also form an electrical connection to the second metal layer of the MIM capacitor, as needed. As such, an improved MIM capacitor has been formed that includes a high-quality capacitor dielectric layer that enables the MIM transistor to be scaled down. With an improved capacitor dielectric, MIM capacitors with a thinner electrical oxide thickness can be realized at equivalent leakage values.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A fabrication process for a MIM capacitor, comprising:
providing a substrate;
depositing a first metal layer on a dielectric layer of the substrate;
forming an interfacial layer on the first metal layer, wherein the interfacial layer has a hydroxyl terminated surface;
depositing a capacitor dielectric layer on the interfacial layer using an ALD process; and
depositing a second metal layer on the capacitor dielectric layer.

2. The method of claim 1, wherein the substrate includes a transistor for use in a 1T1C memory cell.

3. The method of claim 2, wherein the first metal layer is deposited on a portion of the dielectric layer that includes a via that electrically couples the first metal layer to the transistor.

4. The method of claim 1, wherein the forming of the interfacial layer comprises depositing a thin layer of a metal oxide having a thickness less than or equal to 6 Å onto the first metal layer, wherein the metal oxide is selected from the group consisting of titanium oxide, tantalum oxide, and titanium oxynitride.

5. The method of claim 1, wherein the forming of the interfacial layer comprises oxidizing a surface of the first metal layer with an oxygen plasma.

6. The method of claim 1, wherein the forming of the interfacial layer comprises evaporating a thin metal oxide onto the surface of the first metal layer, wherein the metal oxide is selected from the group consisting of aluminum oxide, hafnium oxide, zirconium oxide, and tantalum oxide.

7. A MIM capacitor comprising:
a semiconductor substrate;
a first metal layer on the semiconductor substrate;
an interfacial layer on the first metal layer, wherein the interfacial layer has a hydroxyl terminated surface;
a capacitor dielectric layer on the hydroxyl terminated surface of the interfacial layer; and
a first metal layer on the capacitor dielectric layer.

8. The MIM capacitor of claim 7, wherein the substrate includes:
a transistor for use in a 1T1C memory cell; and
a via that electrically couples the transistor to the first metal layer.

9. The MIM capacitor of claim 7, wherein the first metal layer comprises at least one metal selected from the group consisting of copper, aluminum, magnesium, tin, zirconium, indium, tungsten, and silver.

10. The MIM capacitor of claim 7, wherein the first metal layer has a thickness that ranges between around 1 nm and around 100 nm.

11. The MIM capacitor of claim 7, wherein the interfacial layer is selected from the group consisting of titanium oxide, tantalum oxide, titanium oxynitride, aluminum oxide, hafnium oxide, zirconium oxide, and tantalum oxide.

12. The MIM capacitor of claim 7, wherein the interfacial layer has a thickness that ranges up to around 6 Å.

13. The MIM capacitor of claim 7, wherein the capacitor dielectric layer is selected from the group consisting of silicon dioxide, silicon nitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

14. The MIM capacitor of claim 7, wherein the capacitor dielectric layer has a thickness that ranges between around 3 nm and around 20 nm.

15. The MIM capacitor of claim 7, wherein the second metal layer comprises at least one metal selected from the group consisting of copper, aluminum, magnesium, tin, zirconium, indium, tungsten, and silver.

16. The MIM capacitor of claim 7, wherein the second metal layer has a thickness that ranges between around 1 nm and around 100 nm.
